(19) United States
(12) Patent Application Publication
(10) Pub. No.: US 2004/0188703 A1
(43) Pub. Date: Sep. 30, 2004

(54) Switch

(76) Inventors: Tongwei Cheng, Cork (IE); James Craig Greer, Waterfall (IE); Alan Mathewson, Cork (IE); Michael Peter Kennedy, Cork (IE)

Correspondence Address: JACOBSON HOLMAN PLLC, 400 SEVENTH STREET N.W., SUITE 600, WASHINGTON, DC, 20004, US

(21) Appl. No.: 10/793,940

(22) Filed: Mar. 8, 2004

(30) Foreign Application Priority Data
Mar. 7, 2003 (IE) 2003/0167

(51) Int. Cl. H03K 19/20

(52) U.S. Cl. 257/107

(57) ABSTRACT

An electrical switch performs multi-polar switching. A HDFET structure has a source (2) at one terminal and two drains (3(a) and 3(b)) providing isolated terminals at the opposite end. The drains (3(a) and 3(b)) are separated by an insulator (8). N+ gates (6, 7) are at each side of a channel (5) linking the source (2) with the drains (3(a), 3(b)). Bias of the gates (6, 7) is controlled to control depletion regions (21, 22) to switch on or off current flow (A, B) between the source (2) and the drains (3(a), 3(b)).

### INTRODUCTION

The invention relates to electrical switches in which current is directed to one of two or more terminals.

At present such switches are typically implemented electromagnetically.

The invention is directed towards providing for a more compact switch and/or which is more susceptible to high-volume production, and/or which is more easily integrated with electronic circuits.

### SUMMARY OF THE INVENTION

According to the invention, there is provided an electrical switch comprising:

a source;

a drain;

a semiconductor channel extending between the source and the drain;

a gate on the channel at a location between the source and the drain;

wherein the gate and the channel are doped to provide a semiconductor junction having a depletion region in the channel under some bias conditions;

the channel configuration is such that the depletion region can block current between the source and the drain under an off gate bias condition.

In one embodiment, there are at least two sources or at least two drains, and the gate-channel depletion region controls connections between the source or sources and the drain or drains.

In another embodiment, there is one source and two drains.

In a further embodiment, there is at least one gate on each of a pair of lateral channel sides, each gate providing a junction between itself and the channel.

In one embodiment, there are two drains, the drains are separated by an insulator, and each gate controls a current path between the source and one the drains.

In a further embodiment, the source is of p+ doping.

In one embodiment, the drains are of p+ doping.

In another embodiment, the channel is p doping.

In a further embodiment, the gate is of n+ doping.

In one embodiment, the channel is buried within a body connecting the source and the drain.

In another embodiment, the channel is a layer within said body.

In a further embodiment, the switch has the structure of a heterodimensional field effect transistor (HDFET).

In another aspect, the invention provides a switch circuit comprising a switch as defined above and a bias controller for controlling bias of the gate to set a desired electrical interconnection of the source and drain.

### DETAILED DESCRIPTION OF THE INVENTION

The invention will be more clearly understood from the following description of some embodiments thereof, given by way of example only with reference to the accompanying drawings in which:

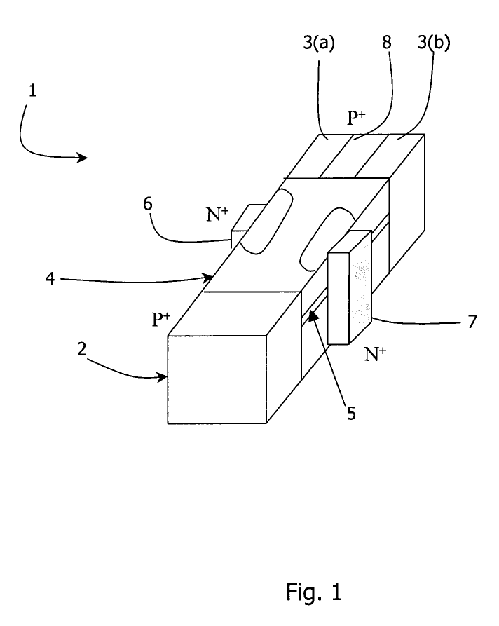

FIG. 1 is a diagrammatic perspective view from above of a switch of the invention;

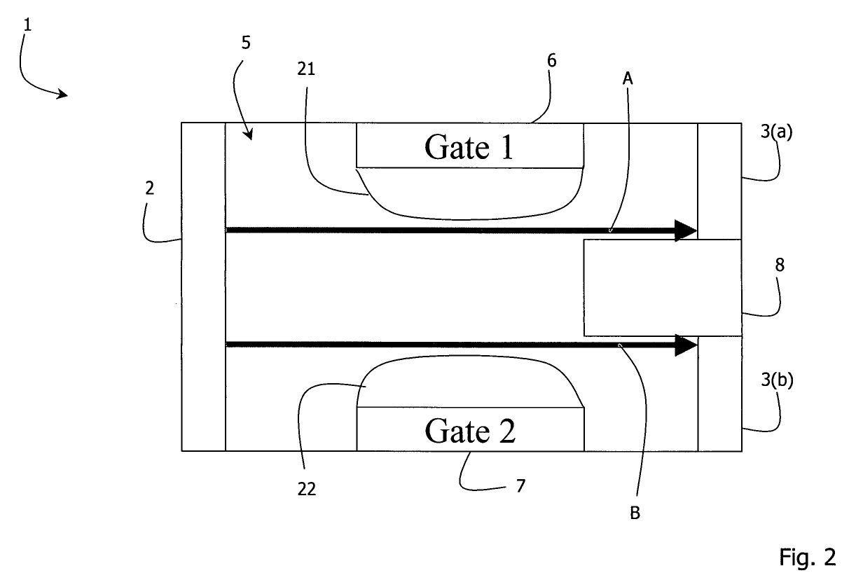

FIG. 2 is a plan view of the switch, showing the manner in which it operates; and

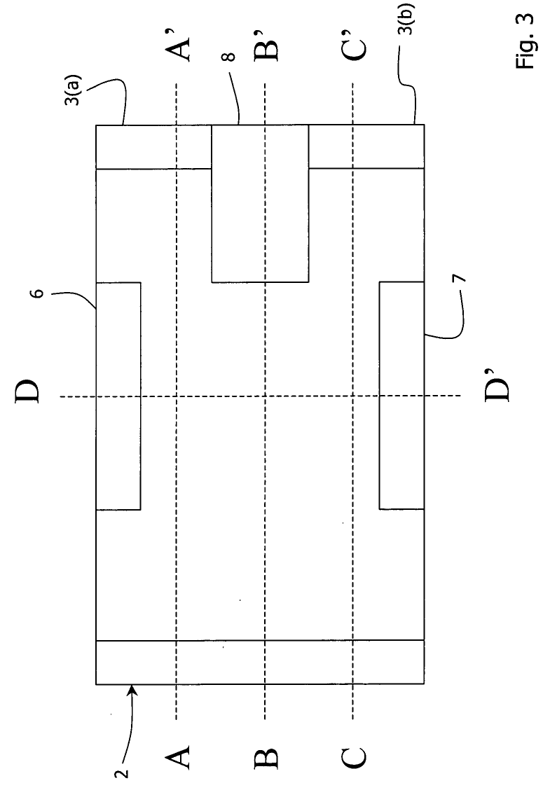

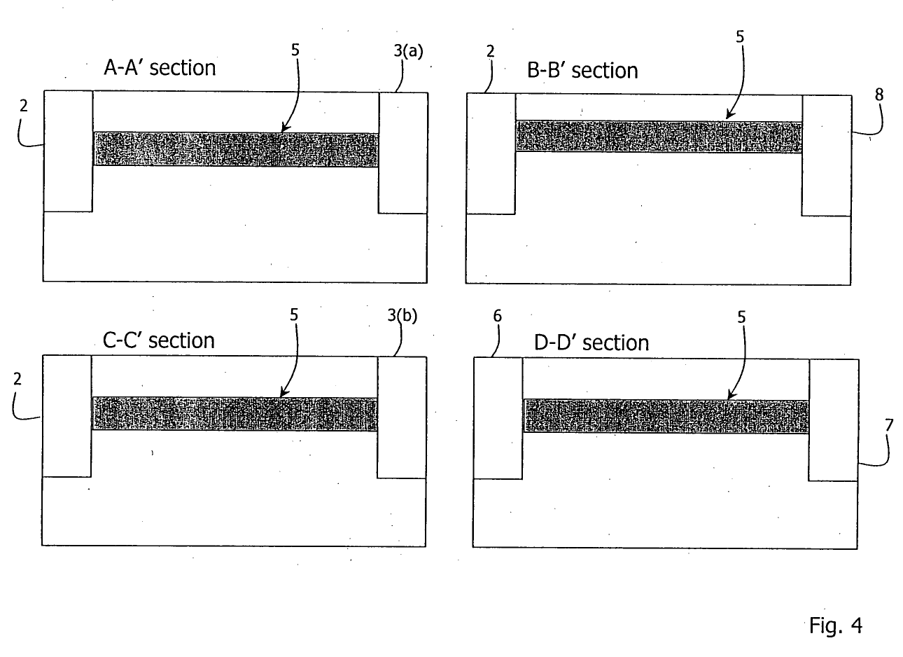

FIG. 3 is a plan view showing a number of cross-sectional lines, and FIGS. 4 to 8 inclusive each show cross-sectional views in the directions of the lines A-A′, B-B′, C-C′, and D-D′ for an operating mode.

Referring to FIG. 1 a switch 1 comprises in a heterodimensional field effect transistor (HDFET) structure:

a p+ source 2,

isolated p+ drains 3(a) and 3(b) at the opposite end of the structure;

a body 4 having a 2D hole GaAs p+ channel 5,

n+ gates 6 and 7 on the lateral sides of the body 4, and

an insulator 8 separating the drains 3(a) and 3(b).

The gates have n-type doping and the channel 5 doping is p-type. Thus the gates and the channel form PN junctions.

Operation of the switch 1 is simple. The biases of the gates 6 and 7 are controlled so that a conducting path in the channel 5 extends:

between the source 2 and the drain 3(a) (ON, one direction),

between the source 2 and the drain 3(b) (ON other direction),

between the source 2 and the insulator (OFF), or

there is no conducting channel (OFF).

The switch is therefore a multipolar electrical switch for handling currents normally handled by electromechanical switches or relays.

As shown in FIG. 2, the gates 6 (“G1”) and 7 (“G2”) apply biases V_{G1} and V_{G2} to the channel 5. These cause depletion regions 21 and 22 to arise in the channel 5. Current paths arise between the source 2 and one, both, or neither drain 3(a), 3(b) according to configurations of the depletion regions. The current path from the source 2 to the drain 3(a) is indicated by the arrow A, and that from the source 2 to the drain 3(b) by the arrow B. This drawing shows diagrammatically how the depletion regions 21 and 22 can encroach into the current paths within the channel 5. In the mode illustrated here the gate 6 bias, V_{G1}, is greater than zero, and the gate 7 bias, V_{G2} is also greater than zero.

The normal operating ranges for the switch I are as follows:

V_{D1}=V_{D2}<0 V;

V_{S}=0 V; and

V_{G1},V_{G2}≧0 V

where V_{D1} is the voltage of the drain 3(a), V_{D2} that of the drain 3(b), and V_{S} that of the source 2.

Reversing the drain-source voltage polarity reverses the current flow.

Referring to FIG. 3, lines for various cross-section views A-A′, B-B′, C-C′ and D-D′ are shown. FIGS. 4-8 each show status of the channel 5 on these cross-sections for an operating mode.

FIG. 4 is a set of cross-sectional views along these lines for V_{G1},V_{G2}<0 V, in which there are no depletion regions and the source is electrically connected to both drains. The shaded portion of the channel 5 is free to conduct (has no depletion region).

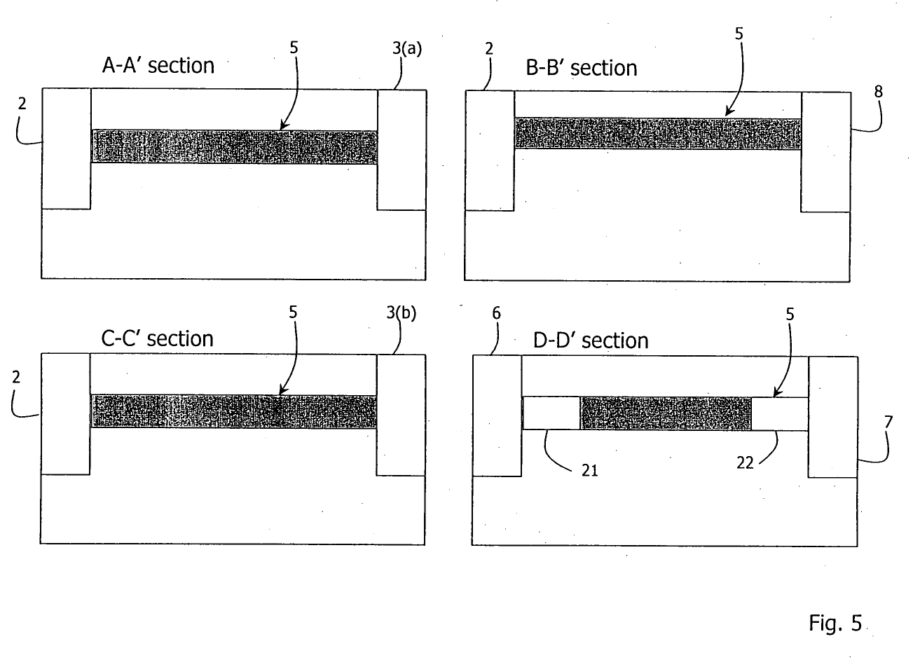

FIG. 5 shows corresponding views for 0<V_{G1}=V_{G2}<V_{pinch}, in which V_{pinch} is the bias voltage required to create a side gate depletion area large enough to electrically isolate the source from either drain 3(a) or 3(b). The shaded portion of the channel 5 is free to conduct.

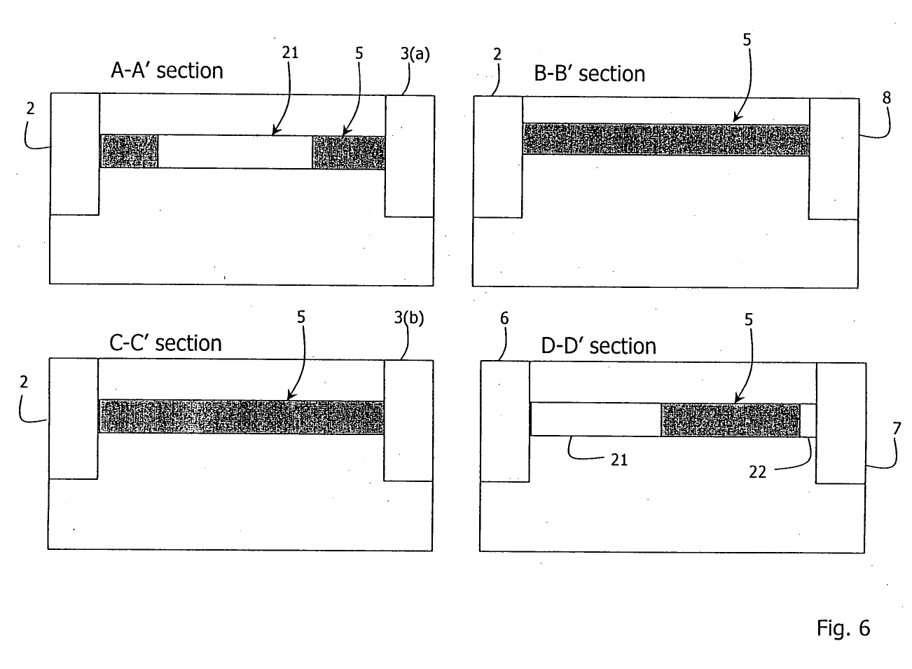

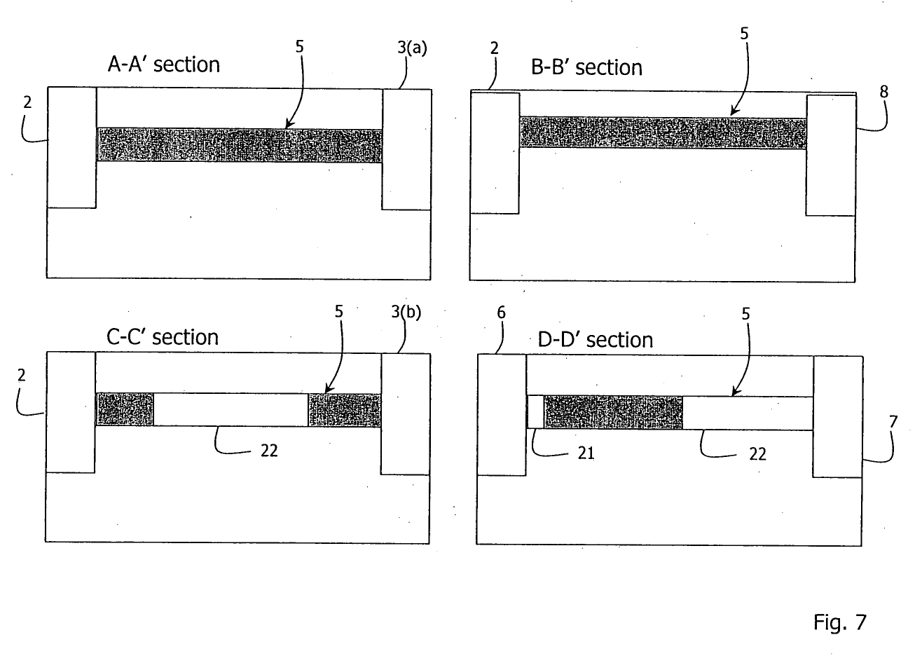

In FIG. 6, V_{G1}≧V_{pinch} and V_{G2}<V_{pinch}. The source 2 is connected only to the drain 3(b) due to spread of the depletion region 21 from the gate 6. The opposite scenario is shown in FIG. 7.

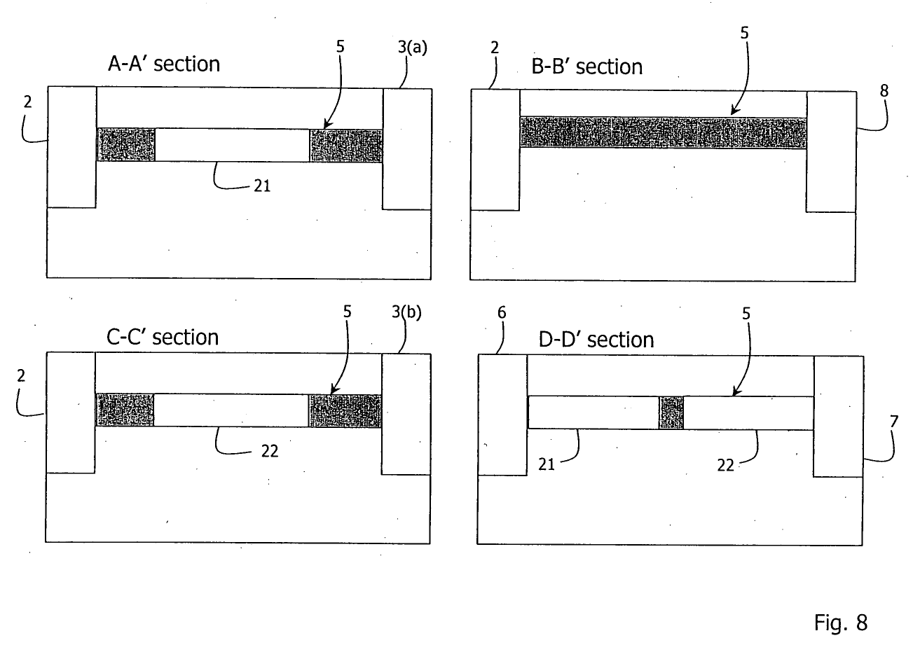

FIG. 8 shows the scenario for which V_{G1}=V_{G2}≧V_{pinch}. The current path is only in the centre, and so the source is isolated from both drains.

It will be appreciated that the invention provides a semiconductor switch which is very versatile in terms of switching configurations, is subject to high volume semiconductor production processes, and is easily controlled according to a simple biasing scheme. Also, the switch has a low insertion loss.

The invention is not limited to the embodiments described but may be varied in construction and detail. For example, the configuration and/or number of sources and drains may be increased or changed to suit switching requirements for any application. There may, for example, be two sources and one or more than two drains.

1. An electrical switch comprising:
a source;
a drain;
a semiconductor channel extending between the source and the drain;
a gate on the channel at a location between the source and the drain;
wherein the gate and the channel are doped to provide a semiconductor junction having a depletion region in the channel under some bias conditions;
the channel configuration is such that the depletion region can block current between the source and the drain under an off gate bias condition.

2. An electrical switch as claimed in claim 1, wherein there are at least two sources or at least two drains, and the gate-channel depletion region controls connections between the source or sources and the drain or drains.

3. An electrical switch as claimed in claim 2, wherein there is one source and two drains.

4. An electrical switch as claimed in claim 2, wherein there is at least one gate on each of a pair of lateral channel sides, each gate providing a junction between itself and the channel.

5. An electrical switch as claimed in claim 4, wherein there are two drains, the drains are separated by an insulator, and each gate controls a current path between the source and one the drains.

6. An electrical switch as claimed in claim 1, wherein the source is of p+ doping.

7. An electrical switch as claimed in claim 6, wherein the drains are of p+ doping.

8. An electrical switch as claimed in claim 6, wherein the channel is p doping.

9. An electrical switch as claimed in claim 6, wherein the gate is of n+ doping.

10. An electrical switch as claimed in claim 1, wherein the channel is buried within a body connecting the source and the drain.

11. An electrical switch as claimed in claim 10, wherein the channel is a layer within said body.

12. An electrical switch as claimed in claim 1, wherein the switch has the structure of a heterodimensional field effect transistor (HDFET)

13. A switch circuit comprising a switch as claimed in claim 1 and a bias controller for controlling bias of the gate to set a desired electrical interconnection of the source and drain.
